(19) United States
(12) Patent Application Publication
(10) Pub. No.: US 2009/0218934 A1
(43) Pub. Date: Sep. 3, 2009

(54) ORGANIC LIGHT-EMITTING DEVICE

(75) Inventors: Won-Jun Song, Suwon-si (KR); Soo-Jin Park, Suwon-si (KR)

Correspondence Address: STEIN MCEWEN, LLP, 1400 EYE STREET, NW, SUITE 300, WASHINGTON, DC, 20005, US

(73) Assignee: Samsung SDI Co., Ltd., Suwon-si (KR)

(21) Appl. No.: 12/205,119

(22) Filed: Sep. 5, 2008

(30) Foreign Application Priority Data
Mar. 3, 2008 (KR) 2008-19618

(51) Int. Cl. H01J 1/63

(52) U.S. Cl. 313/504

(57) ABSTRACT

An organic light-emitting device comprising: a first electrode; a second electrode; an emissive layer; a first hole injecting layer disposed between the first electrode and the emissive layer; a second hole injecting layer disposed between the first electrode and the emissive layer; and an electron transporting layer disposed between the emissive layer and the second electrode, wherein the first hole injecting layer comprises a metal fluoride, the second hole injecting layer comprises molybdenum oxide, and the electron transporting layer comprises a metal compound represented by Formula 1 below:

XₐY_{b} <Formula 1>

X is one of an alkaline metal, an alkaline earth metal, and a transition metal,

Y is one of a Group 7 element and a C₁-C₂₀ organic group,
a is 1 to 3, and
b is 1 to 3.

### CROSS-REFERENCE TO RELATED APPLICATION

This application claims the benefit of Korean Patent Application No. 2008-19618, filed on Mar. 3, 2008 in the Korean Intellectual Property Office, the disclosure of which is incorporated herein by reference.

### BACKGROUND OF THE INVENTION

1. Field of the Invention

Aspects of the present invention relate to an organic light-emitting device, and more particularly, to an organic light-emitting device with improved driving voltage, light emitting efficiency, and life span characteristics. Aspects of the present invention relate to developing a premium organic light-emitting device, which includes a decrease in power consumption and life span improvement of the organic light-emitting device.

2. Description of the Related Art

Organic light-emitting devices emit light by a coupling of electrons and holes in an organic film disposed between two electrodes when a voltage potential is applied to the organic film Organic light-emitting devices enable implementation of light-weight and thin information display devices with high image quality, fast response time, and wide viewing angle. This has become a driving force of rapid growth in organic light-emitting display device technology; and currently, organic light-emitting devices are used in mobile phones, as well as other premium information display devices.

Such growth in organic light-emitting devices has rendered inevitable competition with other information display devices, such as TFT-LCDs, both in the academic field and the industrial technology field. And, conventional organic light-emitting devices are facing a great challenge of overcoming technological limitations, such as improving device efficiency and life span and decreasing power consumption, which remain as the biggest factors hindering the quantitative and qualitative growth of the organic light-emitting devices.

### SUMMARY OF THE INVENTION

Aspects of the present invention provide an organic light-emitting device with an easier injection of two charges, decreased voltage and power consumption, and improved driving voltage, light emitting efficiency and life span.

According to an aspect of the present invention, there is provided an organic light-emitting device comprising: a first electrode; a second electrode; an emissive layer disposed between the first electrode and the second electrode; a first hole injecting layer disposed between the first electrode and the emissive layer, the first hole injecting layer comprising a metal fluoride and a first hole injecting material; a second hole injecting layer disposed between the first electrode and the emissive layer, the second hole injecting layer comprising molybdenum oxide and a second hole injecting material; and an electron transporting layer disposed between the emissive layer and the second electrode, the electron transporting layer comprising an electron transporting material and a metal compound represented by Formula 1 below:

XₐY_{b} <Formula 1>
X is one selected from the group consisting of an alkaline metal, an alkaline earth metal, and a transition metal,
Y is one selected from the group consisting of a Group 7 element and a C₁-C₂₀ organic group,
a is 1 to 3, and
b is 1 to 3.

According to aspects of the present invention, the device may further include a second electron transporting layer comprising the metal compound represented by Formula 1 and the electron transporting material.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A and 1B are each cross-sectional views schematically illustrating structures of an organic light-emitting device, according to aspects of the present invention;

FIG. 2 is an energy band diagram schematically illustrating the differences between HOMO levels and LUMO levels of each layer of the organic light-emitting device of FIG. 1A, according to aspects of the present invention;

FIG. 3 is a graph illustrating the current efficiency characteristics of organic light-emitting devices according to aspects of the present invention and to a conventional embodiment; and

FIG. 4 is a graph illustrating the power consumption of organic light-emitting devices according to aspects of the present invention and to a conventional organic light-emitting device.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the aspects of the present invention by referring to the figures. As used herein, language reciting that a feature is one of a list indicates that the feature may include one of each of the list or include only one selected from the list.

Hereinafter, aspects of the present invention will be described in more detail. In order to implement an organic light-emitting device with high efficiency, charge balance at an emissive layer is very important.

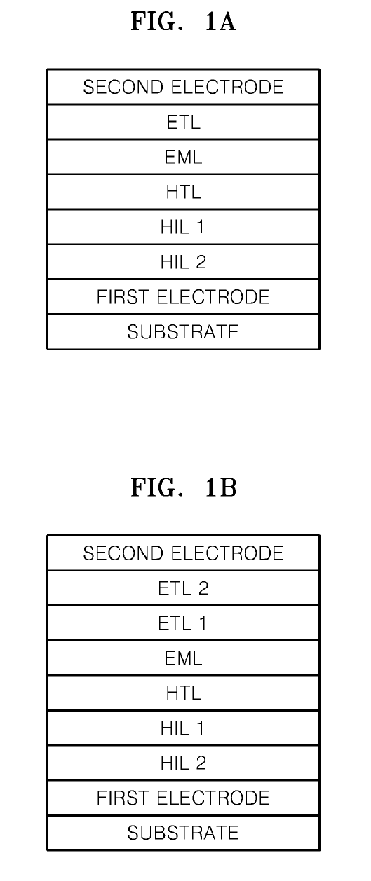

FIGS. 1A and 1B are each cross-sectional views schematically illustrating structures of an organic light-emitting device, according to embodiments aspects of the present invention. In FIG. 1A the organic light-emitting device includes first and second electrodes, the first electrode being disposed on a substrate. Although not shown, an insulating layer may be disposed between the first electrode and the substrate. Further, the substrate may be transparent or opaque, according to aspects of the present invention. An electron transport layer (ETL); an emissive layer (EML); a hole transport layer (HTL); and a hole injection layer, including first and second hole injection layers (HIL 1) and (HIL 2), are disposed between the first and second electrodes. The ETL is disposed opposite the EML from the HTL, HIL 1, and HIL 2. Although shown as having the ETL disposed near the second electrode and the HIL 1 and HIL 2 near the first electrode, aspects of the present invention are not limited thereto such that the ETL, HTL, HIL 1, and HIL 2 may be arranged between the first and second electrodes according to voltages applied thereto. In contrast to a conventional organic light-emitting device, the organic light-emitting device according to aspects of the present invention does not require an electron injection layer, which is generally disposed between the ETL and the second electrode in the configuration as shown in FIG. 1A.

FIG. 1B illustrates another embodiment of the organic light-emitting device according to aspects of the present invention. Again, the organic light-emitting device of FIG. 1B includes first and second electrodes, the first electrode being disposed on a substrate. The organic light-emitting device further includes electron transport layer, including first and second electron transport layers (ETL 1) and (ETL2); an EML; an HTL, and a hole injection layer, including HIL 1 and HIL 2, which are disposed between the first and second electrodes. The ETL 1 and ETL 2 are disposed opposite the EML from the HTL, HIL 1, and HIL 2. Although shown as having the ETL 1 and ETL 2 disposed near the second electrode and the HIL 1 and HIL 2 near the first electrode, aspects of the present invention are not limited thereto such that the ETL 1, ETL 2, HTL, HIL 1, and HIL 2 may be arranged between the first and second electrodes according to voltages applied thereto. In contrast to a conventional organic light-emitting device, the organic light-emitting device according to aspects of the present invention does not require an electron injection layer, which is generally disposed between the ETL 2 and the second electrode in the configuration as shown in FIG. 1B.

According to aspects of the present invention, a double-layered hole injecting layer is provided, the double-layered hole injecting layer including a first hole injecting layer HIL 1 and a second hole injecting layer HIL 2. The first hole injecting layer HIL 1 includes a metal fluoride and a first hole injecting material. The second hole injecting HIL 2 layer includes a molybdenum oxide and a second hole injecting material. Aspects of the present invention also provide an electron transporting layer ETL including a metal compound represented by Formula 1 below and an electron transporting material.

XₐY_{b} <Formula 1>
X is one selected from the group consisting of an alkaline metal, an alkaline earth metal, and a transition metal,
Y is one selected from the group consisting of a Group 7 element and a C₁-C₂₀ organic group,
a is 1 to 3, and
b is 1 to 3.

The first hole injecting layer HIL 1 of the organic light-emitting device according to aspects of the present invention includes a mixture of the metal fluoride and the first hole injecting material.

Generally, materials used for decreasing the hole injecting barrier are used as a pure organic base material; and in this case, the materials are designed with a purpose of minimizing the energy gap between the electrodes and the organic materials. However, if the first hole injecting layer HIL 1, including the metal fluoride mixture according to aspects of the present invention, is used on an electrode interface, a dipole moment is generated on the electrode interface so as to enable greater injection of holes upon application of an electric field to the organic light-emitting device (i.e., an induced dipole).

Metal of the metal fluoride may be a Group 1 element or a Group 2 element, and the metal fluoride may be, for example, one of LiF, NaF, MgF₂, F₁₆—CuPc (copper phthalocyanine), F₈—CuPc, F₄-TCNQ (tetra-cyanoquinodimethane), and CsF.

The mixing ratio between the metal fluoride and the first hole injecting material is 1:1 to 3:1. If the mixing ratio is less than 1:1, the amount of the metal fluoride included in the first hole injecting layer HIL 1 is too small and the driving voltage decrease is small. If the mixing ratio is greater than 3:1, of the amount of the metal fluoride included in the first hole injecting layer HIL 1 is too great and the driving voltage increases.

Moreover, the organic light-emitting device according to aspects of the present invention may include the second hole injecting layer HIL 2, which includes a mixture of a molybdenum oxide and the second hole injecting material.

Similarly, the mixing ratio between the molybdenum oxide and the second hole injecting material may be 1:1 to 3:1. If the mixing ratio is less than 1:1, the amount of the molybdenum oxide included in the second hole injecting layer HIL 2 is too small and the driving voltage decrease is small. If the mixing ratio is greater than 3:1, the amount of the molybdenum oxide included in the second hole injecting layer HIL 2 is too great and the driving voltage increases.

If the mixture including the molybdenum oxide according to aspects of the present invention is used for forming the second hole injecting layer HIL 2, charge transport density can be increased using the electroconductivity of the molybdenum oxide, and the intensity of the electric field required to move the overall charges can be lowered by decreasing the resistance within the organic light-emitting device. Moreover, the energy trap distribution present in the organic structure can be decreased, and the surface morphology can be improved, thereby lowering the contact resistance and preventing charge accumulation.

The first hole injecting material and the second hole injecting material may each independently be a hole injecting layer-forming material such as copper phthalocyanine; 1,3,5-tricarbazolylbenzene; 4,4′-biscarbazolylbiphenyl; polyvinylcarbazole; m-biscarbazolylphenyl; 4,4′-biscarbazolyl-2,2′-dimethylbiphenyl; 4,4′,4″-tri(N-carbazolyl)triphenylamine (TCTA); 4,4′,4″-tris(3-methylphenylamino)triphenylamine (m-MTDATA); 1,3,5-tri(2-carbazolylphenyl)benzene; 1,3,5-tris(2-carbazolyl-5-methoxyphenyl)benzene; bis(4-carbazolylphenyl)silane; N,N′-bis(3-methylphenyl)-N,N′-diphenyl-[1,1-biphenyl]-4,4′-diamine (TPD); N,N′-di(naphthalen-1-yl)-N,N′-diphenyl benzidine (α-NPD); and/or N,N′-diphenyl-N,N′-bis(1-naphthyl)-(1,1′-biphenyl)-4,4′-diamine (NPB).

Preferably, the thickness ratio between the first hole injecting layer HIL 1 and the second hole injecting layer HIL 2 may be 1:9 to 9:1. If the thickness ratio between the first hole injecting layer HIL 1 and the second hole injecting layer HIL 2 is smaller than 1:9, such that the thickness of the first hole injecting layer HIL 1 is too thin relative to the second hole injecting layer HIL 2, the induced dipole effect becomes small, and there is no decreasing effect in the driving voltage; and if the thickness ratio is greater than 9:1 such that the first hole injecting layer HIL 1 is relatively thicker than the second hole injecting layer HIL 2, the driving voltage may increase.

The organic light-emitting device including the first hole injecting material and the second hole injecting material according to aspects of the present invention has improved driving voltage, light-emitting efficiency, and life span. Particularly, life span degradation is minimized during digital driving (i.e. constant voltage driving).

As described above, the electron transporting layer ETL includes a metal compound represented by Formula 1 below and an electron transporting material.

XₐY_{b} <Formula 1>
X is one selected from the group consisting of an alkaline metal, an alkaline earth metal, and a transition metal,
Y is one selected from the group consisting of a Group 7 element and a C₁-C₂₀ organic group,
a is 1 to 3, and
b is 1 to 3.

X in Formula 1 may be Li, Cs, Na, Ba, or Mg; and Y may be F, quinolate, or acetoacetate. The metal compound represented by Formula 1 may be at least one selected from the group consisting of lithium quinolate, sodium quinolate, lithium acetoacetate, magnesium acetoacetate, lithium fluoride, cesium fluoride, sodium fluoride; and mixtures thereof.

In addition, the electron transporting layer ETL includes an electron transporting material with an electron mobility of 10⁻⁸ cm/Vs or greater at an electric field of 800-1000 (V/cm)^{1/2}, in addition to the electron transporting material. In detail, the organic light-emitting device according to aspects of the present invention may include the electron transporting material including the metal compound represented by Formula 1 above and the electron transporting material as a first electron transporting material. Further, the electron transporting layer ETL may include a second electron transporting layer ETL 2 in addition to the first electron transporting layer ETL 1, wherein the second electron transporting layer ETL 2 includes a second electron transporting material, as described in FIG. 1B.

In such a case of including double-layered electron transporting layers ETL 1 and ETL 2, a greater organic electron injection is possible as compared to when a single-layered electron transporting layer ETL is used, and thus the power consumption is greatly decreased due to the voltage decrease.

The second electron transporting layer ETL 2 includes an electron transporting material with an electron mobility of 10⁻⁸ cm/V or greater, and preferably with an electron mobility of 10⁻⁸ to 10⁻³ cm/V at an electric field of 800 to 1000 (V/cm)^{1/2}, and a specific example of such material may be BeBq2.

The first electron transporting material of the first electron transporting layer ETL 1, as with the second electron transporting layer ETL 2, is formed of an electron transporting material with an electron mobility of 10⁻⁸ cm/Vs or greater, and may have the same or different material composition as the second electron transporting material. However, the first electron transporting material of the first electron transporting layer ETL 1 is formed of the same material as the second electron transporting material of the second electron transporting layer ETL 2 for ease of processing.

The thickness ratio of the first electron transporting layer (ETL 1) and the second electron transporting layer (ETL 2) may be 1:1 to 1:2. An example of the first electron transporting material of the first electron transporting layer (ETL 1) may be BeBq2. An example of the second electron transporting material of the second electron transporting layer (ETL 2) may be Alq3.

The organic light-emitting device according to aspects of the present invention does not require an electron injecting layer as above, and thus may be omitted. The organic light-emitting device according to aspects of the present invention provides easier electron injection without requiring a separate electron injecting layer.

The structure of the organic light-emitting device according to aspects of the present invention is widely diverse. The organic light-emitting device according to aspects of the present invention may include the structures as described with FIGS. 1A and 1B but is not limited thereto. The organic light-emitting device according to aspects of the present invention may also include other structures and may further include either a single layered or a double layered intermediate layers.

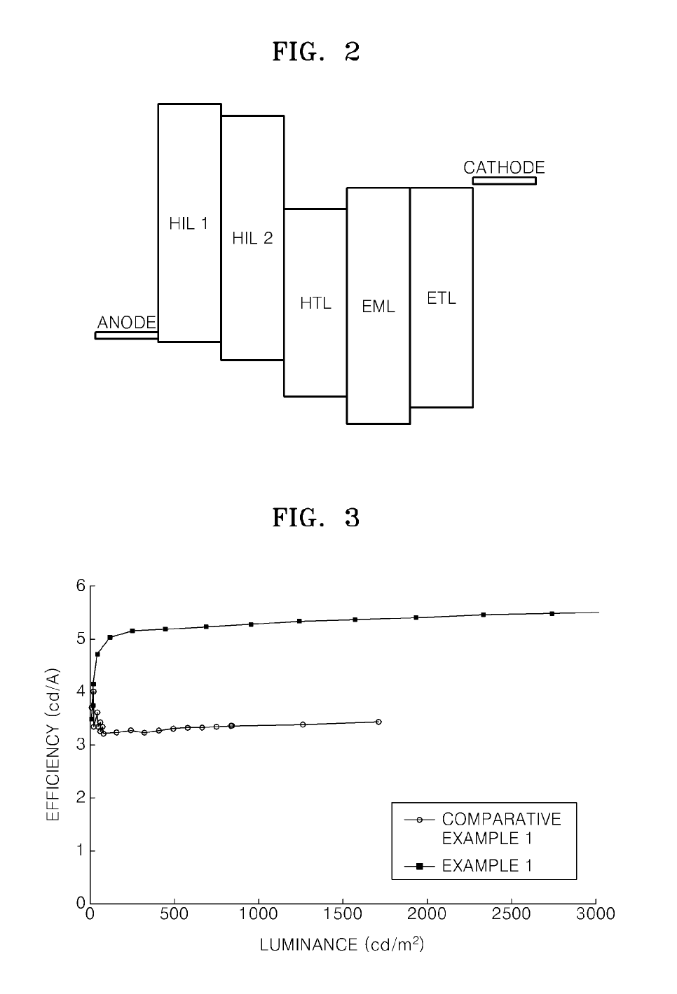

FIG. 2 is an energy band diagram schematically illustrating differences between highest occupied molecular orbital (HOMO) levels and lowest unoccupied molecular orbital (LUMO) levels (i.e., band gaps) of each layer of an organic light-emitting device, according to an embodiment of the present invention. The organic light-emitting device with such a structure according to aspects of the present invention can lower a charge injecting barrier and can decrease the contact resistance of the interface to significantly increase the life span of the organic light-emitting device.

Hereinafter, a method of manufacturing the organic light-emitting device according to an embodiment of the present invention will be described. First, an anode-forming material is coated on a substrate to form an anode as a first electrode. Here, the substrate may be a substrate conventionally used for organic electroluminescent devices, and may preferably be a glass substrate or a transparent plastic substrate with excellent transparency, surface planarity, ease of handling, and water resistance. The anode-forming material may be indium tin oxide (ITO), indium zinc oxide (IZO), tin oxide (SnO₂) and zinc oxide (ZnO), which are transparent and highly conductive. Aspects of the present invention are not limited thereto such that the anode-forming material may be coated on a transfer substrate, removed from the transfer substrate, and adhered to the substrate, among other methods.

Next, a first hole injecting layer (HIL 1) is formed on the first electrode and may be formed using a variety of methods such as vacuum deposition, spin coating, casting, and an LB method. For example, a metal fluoride as the first HIL material and a conventional HIL-forming organic compound may be co-deposited.

Next, a second hole injecting layer (HIL 2) is formed on the HIL 1 and may be formed using a variety of methods such as vacuum deposition, spin coating, casting, and an LB method. For example, molybdenum oxide as the second HIL material and a conventional HIL-forming organic compound may be co-deposited.

When forming the HIL 1 and HIL 2 by vacuum deposition, the conditions of vacuum deposition vary according to the compounds used as the material for the HIL 1 and HIL 2, the structure of the HIL 1 and HIL 2 to be formed, and the thermal properties of the HIL 1 and HIL 2, but generally may be appropriately selected from the ranges of a deposition temperature of 50 to 500° C., a degree of vacuum of 10⁻⁸ to 10⁻³ torr, a deposition rate of 0.01 to 100 Å/sec, and film thickness of 10 Å to 5 μm.

An HTL may be formed by coating an HTL-forming material on the HILs using a method such as vacuum deposition, spin coating, casting, and an LB method, but may preferably be formed by vacuum deposition, because the method is easy to obtain a uniform film, and pin holes are not easily produced. When forming the HTL by vacuum deposition, the conditions of coating may be different according to the compounds used, but may be generally selected from the range of conditions as for forming the HIL 1 and HIL 2.

The material for the HTL is not particularly limited, and thus, N,N′-bis(3-methylphenyl)-N,N′-diphenyl-[1,1-biphenyl]-4,4′-diamine (TPD), and N,N′-di(naphthalene-1-yl)-N,N′-diphenyl benzidine (α-NPD) may be used.

Next, an EML is formed on the HTL. The method of forming the EML may be vacuum deposition, spin coating, casting, or an LB method. A material forming the EML is not particularly limited. More particularly, oxadiazole dimer dyes (Bis-DAOPXP), spiro compounds (Spiro-DPVBi, Spiro-6P), triarylamine compounds, bis(styryl)amine (DPVBi, DSA), 4,4′-bis(9-ethyl-3-carbazovinylene)-1,1′-biphenyl (BCzVBi), perylene, 2,5,8,11-tetra-tert-butylperylene (TPBe), 9H-carbazole-3,3′-(1,4-phenylene-di-2,1-ethene-diyl)bis[9-ethyl-(9C)] (BczVB), 4,4′-bis[4-(di-p-tolylamino)-4′-[(di-p-tolylamino)styryl]stilbene (DPAVB), 4,4′-bis[4-(diphenylamino)styryl]biphenyl (BDAVBi), and bis(3,5-difluoro-2-(2-pyridyl)phenyl-(2-carboxypyridyl)iridium (III) (FlrPic) may be used for a blue color; 3-(2-benzothiazolyl)-7-(dimethylamino)coumarin (Coumarin 6) 2,3,6,7-tetrahydro-1,1,7,7,-tetramethyl-1H,5H,11H-10-(2-benzothiazolyl)quinolizino-[9,9a,1gh] coumarin (C545T), N,N′-dimethyl-quinacrydone(DMQA), and tris(2-phenylpyridine)iridium(III) (Ir(ppy)₃) may be used for a green color; tetraphenylnaphthacene (Rubrene), tris(1-phenylisoquinoline)iridium (III) (Ir(piq)₃), bis(2-benzo[b]thiophene-2-yl-pyridine) (acetylacetonate) iridium (III) (Ir(btp)₂(acac)), tris(dibenzoylmethane)phenanthroline europium (III) (Eu(dbm)₃(phen)), tris[4,4′-di-tert-butyl-(2,2′)-bipyridine]ruthenium (III) complex (Ru(dtb-bpy)₃*2(PF₆)), DCM1, DCM2, Eu (thenoyltrifluoroacetone)₃ (Eu(TTA)₃, and butyl-6-(1,1,7,7-tetramethyl julolidyl-9-enyl)-4H-pyran (DCJTB) may be used for a red color. Moreover, the polymer light-emitting materials may include aromatic compounds including nitrogen and polymers such as phenylene-based, phenylene vinylene-based, thiophene-based, fluorene-based, and spiro-fluorene-based polymers, but are not limited thereto.

The thickness of the EML may be 10 nm to 500 nm, and more preferably, 20 nm to 100 nm. Particularly, the thickness of a blue EML may be 25 nm. If the thickness of the EML is less than 10 nm, leakage current increases, thereby decreasing the efficiency and life span of the organic light-emitting device; and if the thickness of the EML is greater than 500 nm, the increasing rate of the driving voltage becomes too high.

If necessary, the EML may be prepared by adding a light-emitting dopant to an EML host. The material for a fluorescent light-emitting host may include tris(8-hydroxy-quinolinato) aluminum (Alq3), 9,10-di(naphthy-2-yl) anthracene (ADN), 3-tert-butyl-9,10-di(naphthy-2-yl) anthracene (TBADN), 4,4′-bis (2,2-diphenyl-ethene-1-yl)-4,4′-dimethylphenyl (DPVBi), 4,4′-bis(2,2-diphenyl-ethene-1-yl)-4,4′-dimethylphenyl (p-DMDPVBi), tert(9,9′-diarylfluorene)s (TDAF), 2-(9,9′-spirobifluorene-2-yl)-9,9′-spirobifluorene (BSDF), 2,7-bis(9,9′-spirobifluoren-2-yl)-9,9′-spirobifluorene (TSDF) bis(9,9′-diarylfluorene)s (BDAF), and 4,4′-bis(2,2-diphenyl-ethene-1-yl)-4,4′-di-(tert-butyl)phenyl (p-TDPVBi), and the material for a phosphorescent light-emitting host may include 1,3-bis(carbazol-9-yl)benzene (mCP), 1,3,5-tris(carbazol-9-yl)benzene (tCP), 4,4′,4″-tris(carbazol-9-yl)triphenylamine (TcTa), 4,4′-bis(carbazol-9-yl)biphenyl (CBP), 4,4′-bis(9-carbazolyl)-2,2′-dimethyl-biphenyl (CBDP), 4,4′-bis(carbazol-9-yl)-9,9-dimethylfluorene (DMFL-CBP), 4,4-bis(carbazol-9-yl)-9,9-bis(9-phenyl-9H-carbazol)fluorene (FL-4CBP), 4,4′-bis(carbazol-9-yl)-9,9′-di-tolyl-fluorene (DPFL-CBP), and 9,9-bis(9-phenyl-9H-carbazole)fluorene (FL-2CBP).

Here, the content of the light-emitting dopant varies according to the EML-forming material used, but generally, the content may preferably be 1 to 10 parts by weight based on 100 parts by weight of the EML-forming material (total weight of the host and dopant). If the content of the light-emitting dopant is outside the range above, light-emitting properties of an EML device is decreased. For example, DPAVBi may be used as a dopant, and ADN (9,10-di(naphthy-2-yl)anthracene) or TBADN (3-tert-butyl-9,10-di(naphthy-2-yl)anthracene), as shown below, may be used as the fluorescent light-emitting host.

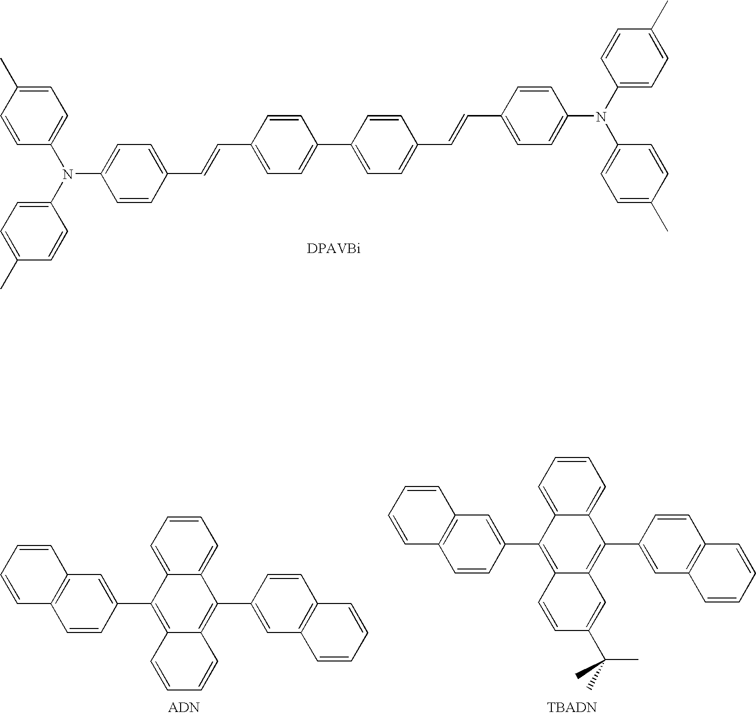

Next, the ETL is formed by depositing the electron transporting material and the metal compound of Formula 1 as previously described according to the vacuum deposition method.

The content of the metal compound of Formula 1 may preferably be 30 to 60 parts by weight based on 100 parts by weight of the electron transporting material. If the metal oxide content is less than 30 parts by weight, the properties of the metal compound become nonfunctional, and if the content is greater than 60 parts by weight, insulating characteristics of the metal compound increase.

The electron transporting material may preferably be a material having an electron mobility of 10⁻⁸ cm/VS or greater, and more particularly 10⁻⁵ to 10⁻³ cm/VS at an electric field of 800-1000 (V/cm)^{1/2}.

If the electron mobility of the ETL is less than 10⁻⁸ cm/VS, the electron injection in the EML is insufficient, which is not desirable in terms of charge balance.

The ETL-forming material may be bis(10-hydroxebenzo[h]quinolinato beryllium (Bebq2), shown as Formula 2 below, or derivatives thereof.

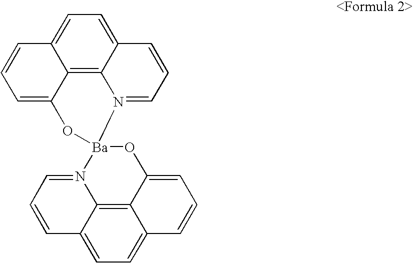

According to aspects of the present invention, an electron injection layer (EIL) need not be included in the organic light-emitting device. However, if an EIL is included, the EIL is next formed on the ETL and may be formed of materials such as LiF, NaCl, CsF, Li₂O, or BaO. The conditions of depositing the ETL and the EIL may be different according to the compounds used, but may be generally selected from the similar range of conditions as for forming the HIL.

Finally, a cathode, as a second electrode, is formed on the ETL or the EIL by depositing a cathode-forming metal using a method such as vacuum deposition or sputtering. The cathode-forming metal may be a metal, an alloy, and an electroconductive compound having a low work function, or mixtures thereof. Specific examples of such materials include Li, Mg, Al, Al—Li, Ca, Mg—In, and Mg—Ag. In addition, a transmitting cathode formed of ITO or IZO may be used in order to obtain a top-emission light-emitting device.

A method of preparing an organic light-emitting device according to another embodiment of the present invention is described as below.

As shown in FIG. 1B, an organic light-emitting device, including a double-layered ETL, is prepared using the same method as previously described, except that an ETL 1 is formed by depositing a electron transporting material on the EML by using vacuum deposition, and that an ETL 2 is formed by depositing the electron transporting material and the metal compound of Formula 1 on the ETL 1 as previously described for the ETL 1 by using vacuum deposition.

Hereinafter, examples of embodiments of the present invention are presented in detail, but the present invention is not limited thereto.

### EXAMPLE 1

### Manufacturing Example of an Organic Light-Emitting Device

An anode was prepared by cutting a Corning 150 cm² (1200 Å) ITO glass substrate into a size of 50 mm×50 mm×0.7 mm, sonicating the substrate for 5 minutes using isopropyl alcohol and deionized water, irradiating the substrate with UV light for 30 minutes, and exposing the substrate to ozone.

First, NPB and MgF₂ were co-deposited on the substrate to form an HIL 1 with a thickness of 50 Å. Next, molybdenum oxide and m-MTDATA were co-deposited on the HIL 1 to form an HIL 2 with a thickness of 600 Å. NPB was vacuum-deposited on the HIL 2 to form an HTL with a thickness of 40 nm. After forming the HTL as described, 100 parts by weight of Alq3 as a host, and 3 parts by weight of C545T as a dopant were vacuum-deposited on the HTL to form an EML. Then, 50 parts by weight of CsF and 50 parts by weight of Alq3 were vacuum co-deposited on the EML to form an ETL with a thickness of 35 nm. Then, the organic light-emitting device was completed by forming an Al cathode by vacuum-depositing Al to a thickness of 3000 Å on the ETL.

### EXAMPLE 2

### Manufacturing Example of Organic Light-Emitting Device

An organic light-emitting device was produced using the same method as in Example 1, except that the ETL of Example 2 was formed by vacuum co-depositing 50 parts by weight of lithium fluoride and 50 parts by weight of Alq3.

### COMPARATIVE EXAMPLE 1

### Manufacturing Example of Organic Light-Emitting Device

An organic light-emitting device was produced using the same method as in Example 1, except that the ETL of the Comparative Example 1 only included Alq3.

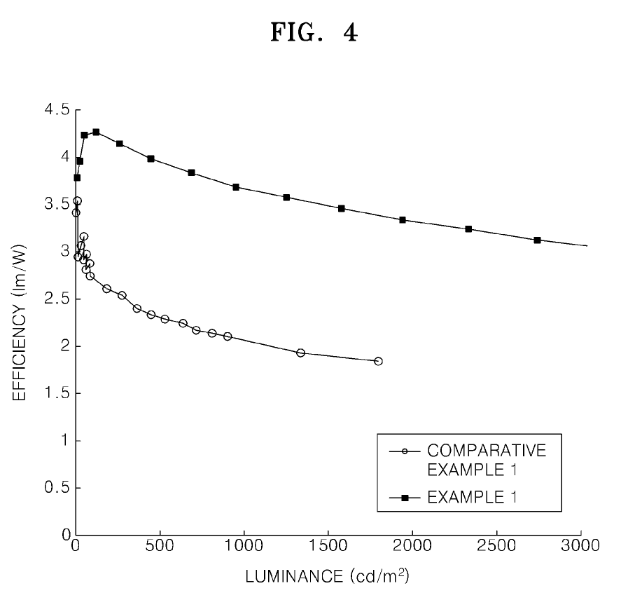

The current efficiencies (cd/A) and power efficiencies (Im/W) with respect to the luminance (cd/m2) of the organic light-emitting devices produced according to Example 1 and Comparative Example 1 were investigated, and the results are shown in FIGS. 3 and 4, respectively. As shown in FIGS. 3 and 4, the Example 1, according to aspects of the present invention, exhibited a current efficiency and a power efficiency about 1.6 and 2 times greater, respectively, than the Comparative Example 1.

According to aspects of the present invention, an organic light-emitting device has excellent electrical characteristics, and uses a hole injecting material suitable for fluorescent and phosphorescent elements of all colors including red, green, blue, and white. Moreover, the organic light-emitting device includes an electron transporting material that significantly improves electron injecting capability without needing to form an electron injecting layer. As a result, the current efficiency and power efficiency of the organic light-emitting device are improved as compared to when conventional electron transporting materials are used, and the charge balance injected into the emissive layer is controlled so that the driving voltage and the life span of the organic light-emitting device are improved. The organic light-emitting device according to aspects of the present invention lowers the injection barrier of the two charges and thus decreases power consumption, and the current efficiency may be maximized by controlling the charge mobility of the hole injecting material and the electron transporting material.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An organic light-emitting device, comprising:
a first electrode;
a second electrode;
an emissive layer disposed between the first electrode and the second electrode;
a first hole injecting layer disposed between the first electrode and the emissive layer, the first hole injecting layer comprising a metal fluoride and a first hole injecting material;
a second hole injecting layer disposed between the first electrode and the emissive layer, the second hole injecting layer comprising molybdenum oxide and a second hole injecting material; and
an electron transporting layer disposed between the emissive layer and the second electrode, the electron transporting layer comprising an electron transporting material and a metal compound represented by Formula 1 below:
XₐY_{b tm <Formula} 1>
in which X is one selected from the group consisting of an alkaline metal, an alkaline earth metal, and a transition metal, Y is one selected from the group consisting of a Group 7 element and a C₁-C₂₀ organic group, a is 1 to 3, and b is 1 to 3.

2. The organic light-emitting device of claim 1, wherein a mixing ratio of the metal fluoride and the first hole injecting material is 1:1 to 3:1.

3. The organic light-emitting device of claim 1, wherein a mixing ratio of the molybdenum oxide and the second hole injecting material is 1:1 to 3:1.

4. The organic light-emitting device of claim 1, wherein a metal of the metal fluoride is a Group 1 element or a Group 2 element.

5. The organic light-emitting device of claim 1, wherein the first hole injecting material and the second hole injecting material are each independently selected from the group consisting of copper phthalocyanine, 1,3,5-tricarbazolylbenzene, 4,4′-biscarbazolylbiphenyl, polyvinylcarbazole, m-biscarbazolylphenyl, 4,4′-biscarbazolyl-2,2′-dimethylbiphenyl, 4,4′,4″-tri(N-carbazolyl)triphenylamine (TCTA), 4,4′,4″-tris(3-methylphenylamino)triphenylamine (m-MTDATA), 1,3,5-tri(2-carbazolylphenyl)benzene, 1,3,5-tris(2-carbazolyl-5-methoxyphenyl)benzene, bis(4-carbazolylphenyl)silane, N,N′-bis(3-methylphenyl)-N,N′-diphenyl-[1,1-biphenyl]-4,4′-diamine (TPD), N,N′-di(naphthalen-1-yl)-N,N′-diphenyl benzidine (α-NPD), N,N′-diphenyl-N,N′-bis(1-naphthyl)-(1,1′-biphenyl)-4,4′-diamine (NPB), poly(9,9-dioctylfluorene-co-N-(4-butylphenyl)diphenylamine) (TFB) and poly(9,9-dioctylfluorene-co-bis-N,N-phenyl-1,4-phenylenediamine) (PFB).

6. The organic light-emitting device of claim 5, wherein a thickness ratio of the first hole injecting layer and the second hole injecting layer is 1:9 to 9:1.

7. The organic light-emitting device of claim 1, wherein X of Formula 1 is one of Li, Cs, Na, Ba, and Mg.

8. The organic light-emitting device of claim 1, wherein Y is one of F, quinolate, and acetoacetate.

9. The organic light-emitting device of claim 1, wherein the metal compound represented by Formula 1 is at least one selected from the group consisting of lithium quinolate, sodium quinolate, lithium acetoacetate, magnesium acetoacetate, lithium fluoride, cesium fluoride, and sodium fluoride.

10. The organic light-emitting device of claim 1, wherein the amount of the metal compound represented by Formula 1 in the electron transporting layer is 30 to 60 parts by weight based on 100 parts by weight of the electron transporting material.

11. The organic light-emitting device of claim 1, wherein electron mobility of the electron transporting material is 10⁻⁸ cm/V or greater at an electric field of 800 to 1000 (V/cm)^{1/2}.

12. The organic light-emitting device of claim 1, wherein the electron transporting material is at least one selected from the group consisting of bis(10-hydroxebenzo[h]quinolinatoberyllium) represented by Formula 2 below, and derivatives thereof:

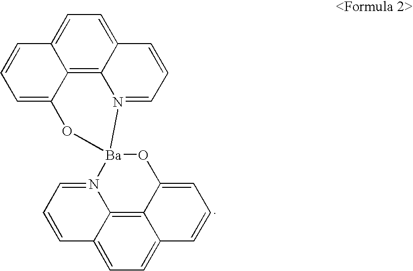

13. The organic light-emitting device of claim 1, wherein the electron transporting layer comprises: a first electron transporting layer comprising the metal compound represented by Formula 1 and a first electron transporting material, the first electron transporting material being the same as the electron transporting material; and
a second electron transporting layer disposed between the first electron transport layer and the second electrode, the second electron transporting layer comprising a second electron transporting material.

14. The organic light-emitting device of claim 13, wherein electron mobility of the second electron transporting material is 10⁻⁸ cm/V or greater at an electric field of 800 to 1000 (V/cm)^{1/2}.

15. The organic light-emitting device of claim 13, wherein the electron mobility of the second electron transporting material is 10⁻⁸ to 10⁻³ cm/V at an electric field of 800 to 1000 (V/cm)^{1/2}.

16. The organic light-emitting device of claim 13, wherein a thickness ratio of the first electron transporting layer and the second electron transporting layer is 2:1 to 1:2.

17. The organic light-emitting device of claim 13, wherein the content of the metal compound represented by Formula 1 in the first electron transporting layer is 30 to 60 parts by weight based on 100 parts by weight of the first electron transporting material.

18. The organic light-emitting device of claim 1, further comprising at least one layer selected from the group consisting of a hole injecting layer, a hole transporting layer, an electron blocking layer, an emissive layer, a hole blocking layer, and an electron transporting layer.

19. The organic light-emitting device of claim 1, wherein the device has one structure selected from the group consisting of first electrode/hole transporting layer/emissive layer/electron transporting layer/second electrode, first electrode/first hole injecting layer/second hole injecting layer/hole transporting layer/emissive layer/electron transporting layer/second electrode, and first electrode/hole injecting layer/hole transporting layer/emissive layer/hole blocking layer/electron transporting layer /second electrode.

20. An organic light-emitting device, comprising:
a first electrode;
a second electrode;
an emissive layer disposed between the first and second electrodes;
a first hole injecting layer disposed between the first electrode and the emissive layer, the first hole injecting layer comprising a first metal fluoride and a first hole injecting material; and
a second hole injecting layer disposed between the first hole injecting layer and the first electrode, the second hole injecting layer comprising a second metal fluoride and a second hole injecting material.

21. The organic light-emitting device of claim 20, wherein metals of the first metal fluoride and the second metal fluoride are independently selected from the group consisting of Group 1 and Group 2 elements.

22. The organic light-emitting device of claim 20, wherein the first metal fluoride and the second metal fluoride are independently selected from the group consisting of LiF, NaF, MgF₂, F₁₆—CuPc, F₈—CuPc, F₄-TCNQ, and CsF.

23. The organic light-emitting device of claim 20, further comprising:
a first electron transporting layer disposed between the second electrode and the emissive layer, the first electron transporting layer comprising a metal compound represented by Formula 1 below and a first electron transporting material; and
a second electron transporting layer disposed between the first electron transport layer and the second electrode, the second electron transporting layer comprising a metal compound represented by Formula 1 below and a second electron transporting material,
XₐY_{b} <Formula 1>
in which X is one selected from the group consisting of an alkaline metal, an alkaline earth metal, and a transition metal, Y is one selected from the group consisting of a Group 7 element and a C₁-C₂₀ organic group, a is 1 to 3, and b is 1 to 3.

24. The organic light-emitting device of claim 23, wherein the first electron transporting material is BeBq2 and the second electron transporting material is Alq3.

25. An organic light-emitting device, comprising:
a first electrode;
a second electrode;
an emissive layer disposed between the first and second electrodes;
a first electron transporting layer disposed between the second electrode and the emissive layer, the first electron transporting layer comprising a metal compound represented by Formula 1 below and a first electron transporting material; and
a second electron transporting layer disposed between the first electron transport layer and the second electrode, the second electron transporting layer comprising a metal compound represented by Formula 1 below and a second electron transporting material,
XₐY_{b} <Formula 1>
in which X is one selected from the group consisting of an alkaline metal, an alkaline earth metal, and a transition metal, Y is one selected from the group consisting of a Group 7 element and a C₁-C₂₀ organic group, a is 1 to 3, and b is 1 to 3.

26. The organic light-emitting device of claim 25, wherein the first electron transporting material is BeBq2 and the second electron transporting material is Alq3.

27. An organic light-emitting device, comprising:
a first electrode;
a second electrode;
an emissive layer disposed between the first and second electrodes;
a first hole injecting layer disposed between the first electrode and the emissive layer, the first hole injecting layer comprising a first metal fluoride and a first hole injecting material;
a second hole injecting layer disposed between the first hole injecting layer and the first electrode, the second hole injecting layer comprising a second metal fluoride and a second hole injecting material; and
an electron transporting layer disposed between the emissive layer and the second electrode, the electron transporting layer comprising a metal compound represented by Formula 1 below and an electron transporting material,
XₐY_{b} <Formula 1>
in which X is one selected from the group consisting of an alkaline metal, an alkaline earth metal, and a transition metal, Y is one selected from the group consisting of a Group 7 element and a C₁-C₂₀ organic group, a is 1 to 3, and b is 1 to 3,
wherein the organic light-emitting device does not include an electron injection layer disposed between the electron transporting layer and the second electrode.
